(19) United States
(12) Patent Application Publication
(10) Pub. No.: US 2020/0325358 A1
(43) Pub. Date: Oct. 15, 2020

(54) SURFACE COATING MATERIAL AND FILM AND STACKED STRUCTURE AND DISPLAY DEVICE AND ARTICLE

(71) Applicant: Samsung Electronics Co., Ltd., Suwon-si (KR)

(72) Inventors: Feifei FANG, Suwon-si (KR); Dmitry ANDROSOV, Suwon-si (KR); Fedosya KALININA, Hwaseong-si (KR); Hye Young KONG, Uijeongbu-si (KR); Byung Ha PARK, Yongin-si (KR); Jung Im HAN, Yongin-si (KR); Sung Hun HONG, Hwaseong-si (KR)

(73) Assignee: Samsung Electronics Co., Ltd., Suwon-si (KR)

(21) Appl. No.: 16/825,026

(22) Filed: Mar. 20, 2020

(30) Foreign Application Priority Data
Apr. 10, 2019 (KR) 10-2019-0042078

(51) Int. Cl. C09D 183/04; C09D 5/00; C03C 17/30

(52) U.S. Cl. CPC C09D 183/04; H01L 27/323; C03C 17/30; C09D 5/00

(57) ABSTRACT

Disclosed are a surface coating material including a first material and a second material having a different structure, wherein the first material has a greater weight average molecular weight than the second material, a film, a stacked structure, a display device, and an article including a glass substrate coated with the surface coating material.

### CROSS-REFERENCE TO RELATED APPLICATION

This application claims priority to and the benefit of Korean Patent Application No. 10-2019-0042078 filed in the Korean Intellectual Property Office on Apr. 10, 2019, the entire contents of which are incorporated herein by reference.

### BACKGROUND

### 1. Field

A surface coating material, a film, a stacked structure, a display device, and an article are disclosed.

### 2. Description of Related Art

A portable electronic device such as a smart phone or a tablet PC may include a functional layer having various functions. In particular, recently, as a touch screen panel recognizing a contact position using a finger or a tool is universalized, a functional layer may be applied on the surface of a display panel in order to improve a surface slipping property and a sense of touch of a touch screen panel.

However, the functional layer may have excellent fingerprint visibility and deteriorated slip properties or the functional layer may have excellent slip properties and deteriorated fingerprint visibility. The functional layer may fail to satisfy both fingerprint visibility and slip properties simultaneously.

### SUMMARY

An embodiment provides a surface coating material having improved slip properties and fingerprint visibility.

Another embodiment provides a film having improved slip properties and fingerprint visibility.

Another embodiment provides a stacked structure including the film.

Another embodiment provides a display device including the film or the stacked structure.

Another embodiment provides an article coated with the surface coating material.

According to an embodiment, a surface coating material includes a first material represented by Chemical Formula 1 and a second material represented by Chemical Formula 2. The first material has a greater weight average molecular weight than the second material.

R¹-(L¹O)ₙ₁—(CH₂)ₘ₁—X—(CH₂)ₘ₂—SiR^{a}R^{b}R^{c} [Chemical Formula 1]

R²-(L²O)ₙ₂—(CH₂)ₘ₃—SiR^{a}R^{b}R^{c} [Chemical Formula 2]

In Chemical Formula 1 and Chemical Formula 2,

R¹ is hydrogen, a substituted or unsubstituted C1 to C20 alkyl group, or a substituted or unsubstituted C1 to C20 alkoxy group,

R² is hydrogen, an amino group, a substituted or unsubstituted C1 to C20 alkyl group, a substituted or unsubstituted C2 to C20 alkenyl group, or a substituted or unsubstituted C1 to C20 alkoxy group,

L¹ and L² are each independently a substituted or unsubstituted C1 to C20 alkylene group,

X is oxygen, *—OL³-*, or *-L³O—* (L³ is a substituted or unsubstituted C1 to C20 alkylene group),

R^{a}, R^{b}, and R^{c} are each independently hydrogen, a substituted or unsubstituted C1 to C20 alkoxy group, a halogen, a hydroxy group, an amino group, a substituted or unsubstituted C1 to C20 alkyl group, a substituted or unsubstituted C6 to C20 aryl group, or a combination thereof, provided that at least one of R^{a}, R^{b}, and R^{c} is a substituted or unsubstituted C1 to C20 alkoxy group, a halogen, or a hydroxy group,
n1 and n2 are each independently an integer of greater than or equal to 0, and
m1, m2, and m3 are each independently an integer of greater than or equal to 1.

In some embodiments, the R² may be hydrogen, a substituted or unsubstituted C1 to C20 alkyl group, or a substituted or unsubstituted C1 to C20 alkoxy group and m3 may be an integer of 3 to 20.

In some embodiments, the R² may be a substituted or unsubstituted C1 to C20 alkoxy group and the first and second materials may be included in a mole ratio of about 99:1 to about 25:75.

In some embodiments, the R² may be hydrogen or a substituted or unsubstituted C1 to C20 alkyl group, a difference between m1+m2 and m3 may be an integer of less than or equal to 6, and the first and second materials may be included in a mole ratio of about 50:50 to about 1:99.

In some embodiments, the R² may be hydrogen or a substituted or unsubstituted C1 to C20 alkyl group, a difference between m1+m2 and m3 may be an integer of 7 to 13, and the first and second materials may be included in a mole ratio of about 99:1 to about 87.5:12.5 or about 12.5:87.5 to about 1:99.

In some embodiments, the R² may be hydrogen or a substituted or unsubstituted C1 to C20 alkyl group, a difference between m1+m2 and m3 may be an integer of greater than or equal to 14, and the first and second materials may be included in a mole ratio of about 99:1 to about 87.5:12.5.

In some embodiments, the R² may be an amino group and m3 may be an integer of 1 to 4. Herein, the first and second materials may be included in a mole ratio of about 99:1 to about 50:50.

In some embodiments, the R² may be a substituted or unsubstituted C2 to C20 alkenyl group and m3 may be an integer of 5 to 7.

In some embodiments, the first and second materials may be included in a mole ratio of about 99:1 to about 87.5:12.5.

In some embodiments, the first material may have a weight average molecular weight of about 350 g/mol to about 1,500 g/mol and the second material may have a weight average molecular weight of about 150 g/mol to about 1,000 g/mol.

In some embodiments, the first material may have a longer chain length than the second material.

In some embodiments, n3 may be 1. Also, n1 and n2 independently may be an integer of 0 to 100 (or 1 to 100). Also, m1, m2, and m3 independently may be an integer of 1 to 100.

In some embodiments, an article may include a glass substrate coated with the surface coating material.

Another embodiment provides a film including a condensation polymerization product of a first material represented by Chemical Formula 1 and a condensation polymerization product of a second material represented by Chemical Formula 2, wherein the first material has a greater weight average molecular weight than the second material.

R¹-(L¹O)ₙ₁—(CH₂)ₘ₁—X—(CH₂)ₘ₂—SiR^{a}R^{b}R^{c} [Chemical Formula 1]

R²-(L²O)ₙ₂—(CH₂)ₘ₃—SiR^{a}R^{b}R^{c} [Chemical Formula 2]

In Chemical Formula 1 and Chemical Formula 2,

R¹ is hydrogen, a substituted or unsubstituted C1 to C20 alkyl group, or a substituted or unsubstituted C1 to C20 alkoxy group,

R² is hydrogen, an amino group, a substituted or unsubstituted C1 to C20 alkyl group, a substituted or unsubstituted C2 to C20 alkenyl group, or a substituted or unsubstituted C1 to C20 alkoxy group,

L¹ and L² are each independently a substituted or unsubstituted C1 to C20 alkylene group,

X is oxygen, *—OL³-*, or *-L³O—* (L³ is a substituted or unsubstituted C1 to C20 alkylene group),

R^{a}, R^{b}, and R^{c} are each independently hydrogen, a substituted or unsubstituted C1 to C20 alkoxy group, a halogen, a hydroxy group, an amino group, a substituted or unsubstituted C1 to C20 alkyl group, a substituted or unsubstituted C6 to C20 aryl group, or a combination thereof, provided that at least one of R^{a}, R^{b}, and R^{c} is a substituted or unsubstituted C1 to C20 alkoxy group, a halogen, or a hydroxy group,
n1 and n2 are each independently an integer of greater than or equal to 0, and
m1, m2, and m3 are each independently an integer of greater than or equal to 1.

In some embodiments, the R² may be hydrogen, a substituted or unsubstituted C1 to C20 alkyl group, or a substituted or unsubstituted C1 to C20 alkoxy group, and m3 may be an integer of 3 to 20.

In some embodiments, the R² may be a substituted or unsubstituted C1 to C20 alkoxy group and the first and second materials may be included in a mole ratio of about 99:1 to about 25:75.

In some embodiments, the R² may be hydrogen or a substituted or unsubstituted C1 to C20 alkyl group, a difference between m1+m2 and m3 is an integer of less than or equal to 6, and the first and second materials may be included in a mole ratio of about 50:50 to about 1:99.

In some embodiments, the R² may be hydrogen or a substituted or unsubstituted C1 to C20 alkyl group, a difference between m1+m2 and m3 may be an integer of 7 to 13, and the first and second materials may be included in a mole ratio of about 99:1 to about 87.5:12.5 or about 12.5:87.5 to about 1:99.

In some embodiments, the R² may be hydrogen or a substituted or unsubstituted C1 to C20 alkyl group, a difference between m1+m2 and m3 may be an integer of greater than or equal to 14, and the first and second materials may be included in a mole ratio of about 99:1 to about 87.5:12.5.

In some embodiments, the R² may be an amino group and m3 may be an integer of 1 to 4. Herein, the first and second materials may be included in a mole ratio of about 99:1 to about 50:50.

In some embodiments, the R² may be a substituted or unsubstituted C2 to C20 alkenyl group, and m3 may be an integer of 5 to 7. Herein, the first and second materials may be included in a mole ratio of about 99:1 to about 87.5:12.5.

In some embodiments, the first material may have a weight average molecular weight of about 350 g/mol to about 1,500 g/mol and the second material may have a weight average molecular weight of about 150 g/mol to about 1,000 g/mol.

In some embodiments, the first material may have a longer chain length than the second material.

In some embodiments, n3 may be 1. Also, n1 and n2 each independently may be an integer of 1 to 100. Also, m1, m2, and m3 each independently may be an integer of 1 to 100.

According to another embodiment, a stacked structure including a substrate and the film is provided.

The substrate may be a ceramic or glass.

According to another embodiment, a display device including the film or the stacked structure is provided.

The slip properties and fingerprint visibility of the functional layer may be improved simultaneously.

### BRIEF DESCRIPTION OF THE DRAWINGS

FIG. 1 is a cross-sectional view showing a display device according to an embodiment,

FIG. 2 is a cross-sectional view showing a display device according to another embodiment,

FIG. 3 is a schematic view showing the first and second materials in a film according to an embodiment, and

FIG. 4 is a cross-sectional view showing a display device according to an embodiment.

### DETAILED DESCRIPTION

Example embodiments of the present disclosure will hereinafter be described in detail and may be easily performed by a person having an ordinary skill in the related art. However, actually applied structures may be embodied in many different forms, and is not to be construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

As used herein, when a definition is not otherwise provided, “substituted” may refer to replacement of a hydrogen atom of a compound by a substituent of a halogen atom, a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

As used herein, when a definition is not otherwise provided, “hetero” may refer to one including 1 to 4 heteroatoms of N, O, S, Se, Te, Si, or P.

As used herein, when specific definition is not otherwise provided, “*” indicates a point where the same or different atom (including a hydrogen atom) or chemical formula is linked.

Hereinafter, “combination” refers to a mixture of two or more and a stack structure of two or more.

Hereinafter, a surface coating material according to an embodiment is described.

A surface coating material according to an embodiment includes a first material represented by Chemical Formula 1 and a second material represented by Chemical Formula 2, wherein the first material has a greater weight average molecular weight than the second material.

R¹-(L¹O)ₙ₁—(CH₂)ₘ₁—X—(CH₂)ₘ₂—SiR^{a}R^{b}R^{c} [Chemical Formula 1]

R²-(L²O)ₙ₂—(CH₂)ₘ₃—SiR^{a}R^{b}R^{c} [Chemical Formula 2]

In Chemical Formula 1 and Chemical Formula 2,

R¹ is hydrogen, a substituted or unsubstituted C1 to C20 alkyl group, or a substituted or unsubstituted C1 to C20 alkoxy group,

R² is hydrogen, an amino group, a substituted or unsubstituted C1 to C20 alkyl group, a substituted or unsubstituted C2 to C20 alkenyl group, or a substituted or unsubstituted C1 to C20 alkoxy group,

L¹ and L² are each independently a substituted or unsubstituted C1 to C20 alkylene group,

X is oxygen, *—OL³-*, or *-L³O—* (L³ is a substituted or unsubstituted C1 to C20 alkylene group),

R^{a}, R^{b}, and R^{c} are each independently hydrogen, a substituted or unsubstituted C1 to C20 alkoxy group, a halogen, a hydroxy group, an amino group, a substituted or unsubstituted C1 to C20 alkyl group, a substituted or unsubstituted C6 to C20 aryl group, or a combination thereof, provided that at least one of R^{a}, R^{b}, and R^{c} is a substituted or unsubstituted C1 to C20 alkoxy group, a halogen, or a hydroxy group,

n1 and n2 are each independently an integer of greater than or equal to 0 (e.g., an integer of 0 to 100),

and

m1, m2, and m3 are each independently an integer of greater than or equal to (e.g., an integer of 0 to 100 and/or 1 to 100). In some embodiments, R¹ may include an amino group.

Conventionally, a composition including a fluorine-containing silicon compound is often used as a surface coating material, but since an initial contact angle is too high, there is a problem that a diffused reflection occurs through a fingerprint smudge phenomenon, when a fingerprint is put, that is, that fingerprint visibility is deteriorated. Accordingly, an attempt to use a non-fluorine-based material capable of improving the fingerprint visibility by setting the initial contact angle to be low in order to improve the fingerprint visibility as a surface coating material has been made, so that a fingerprint may be stretched out, even though the fingerprint is put, but the non-fluorine-based material has a problem that slip properties and durability are greatly deteriorated and that on the surface of a display treated with a surface coating material including the non-fluorine-based material and the like, abrasions are easily found even with naked eyes after about two months compared with an initial surface thereof.

However, the surface coating material according to an embodiment includes the first and second materials having a different structure, that is, the first material represented by Chemical Formula 1 and the second material represented by Chemical Formula 2 and having a smaller weight average molecular weight than that of the first material and thereby may greatly improve slip properties, fingerprint visibility, and durability.

Specifically, since the first material has a larger weight average molecular weight than that of the first material while individually having a particular structure, a form that the first material may lie down on the second material, that is, a self-assembled brush structure may be realized, which may simultaneously improve fingerprint visibility and slip properties.

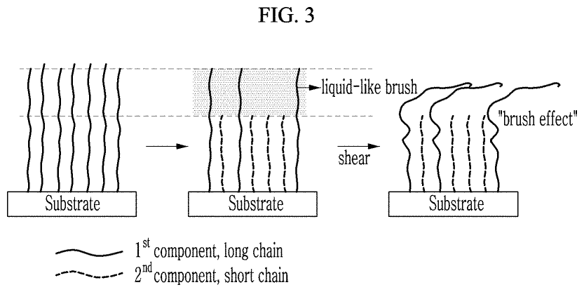

Referring to FIG. 3, the surface coating material or film according to an embodiment is disposed on a substrate, and when the first and second materials internally included in the surface coating material or film are examined, the first material having a long chain length lies down on the second material having a short chain length, and accordingly, a brush effect is realized.

More specifically, the first material represented by Chemical Formula 1 has a structure represented by *—(CH₂)ₘ₁—X—(CH₂)ₘ₂—*, wherein the *—(CH₂)ₘ₁—* and the *—(CH₂)ₘ₂—* have water repellency, and the *—X—* has hydrophilicity, and accordingly, may more easily interact with the second material having a water repellency structure represented by *—(CH₂)ₘ₃—* and more easily form a brush structure where the first material lies down on the second material, which may greatly improve fingerprint visibility, slip properties, and durability of the substrate coated with the surface coating material according to an embodiment.

The chain length of the second material may be different depending on a terminal end structure of the second material, and a mole ratio of the first and second materials may be different depending on the chain lengths of the first and second materials.

For example, in Chemical Formula 2, R² may be hydrogen, a substituted or unsubstituted C1 to C20 alkyl group, or a substituted or unsubstituted C1 to C20 alkoxy group, and m3 may be an integer of 8 to 20.

Specifically, in Chemical Formula 2, R² may be a substituted or unsubstituted C1 to C20 alkoxy group and the first and second materials may be included in a mole ratio of about 99:1 to about 25:75.

Specifically, in Chemical Formula 2, R² may be hydrogen or a substituted or unsubstituted C1 to C20 alkyl group and a difference between m1+m2 of Chemical Formula 1 and m3 of Chemical Formula 2 may be an integer of less than or equal to 6. Herein, the first and second materials may be included in a mole ratio of about 50:50 to about 1:99.

Specifically, in Chemical Formula 2, R² may be hydrogen or a substituted or unsubstituted C1 to C20 alkyl group and a difference between m1+m2 of Chemical Formula 1 and m3 of Chemical Formula 2 may be an integer of 7 to 13. Herein, the first and second materials may be included in a mole ratio of about 99:1 to about 87.5:12.5 or about 12.5:87.5 to about 1:99.

Specifically, in Chemical Formula 2, R² may be hydrogen or a substituted or unsubstituted C1 to C20 alkyl group and a difference between m1+m2 of Chemical Formula 1 and m3 of Chemical Formula 2 may be an integer of greater than or equal to 14. Herein, the first and second materials may be included in a mole ratio of about 99:1 to about 87.5:12.5.

Specifically, in Chemical Formula 2, R² may be an amino group and m3 may be an integer of 1 to 4. Herein, the first and second materials may be included in a mole ratio of about 99:1 to about 50:50.

Specifically, in Chemical Formula 2, R² may be a substituted or unsubstituted C2 to C20 alkenyl group and m3 may be an integer of 5 to 7. Herein, the first and second materials may be included in a mole ratio of about 99:1 to about 87.5:12.5.

As aforementioned, when a type of a terminal end of Chemical Formula 2 is specified, and the chain lengths and the mole ratio of the first and second materials are specified in accordance therewith as aforementioned, the surface coating material and film according to an embodiment may exhibit excellent slip properties, fingerprint visibility, and durability.

For example, the first material may have a weight average molecular weight of about 350 g/mol to about 1,500 g/mol and the second material may have a weight average molecular weight of about 150 g/mol to about 1,000 g/mol. When the first and second materials have weight average molecular weights of the ranges, durability of the surface coating material including the same may be further improved.

For example, the first material may have a longer chain length than the second material.

For example, in Chemical Formula 1, m1 may be a greater integer than m2.

For example, the first material may be represented by Chemical Formula 1-1 or Chemical Formula 1-2.

R¹-(L¹O)ₙ₁—(CH₂)ₘ₁—X—(CH₂)ₘ₂—SiR^{a}R^{b}R^{c} [Chemical Formula 1-1]

In Chemical Formula 1-1,

R¹ is a substituted or unsubstituted C1 to C20 alkoxy group,

L¹ is a substituted or unsubstituted C1 to C20 alkylene group,

X is oxygen,

n1 is an integer of an integer of greater than or equal to 1, and

R^{a}, R^{b}, R^{c}, m1, and m2 are the same as described above.

For example, the L¹ may be a substituted or unsubstituted methylene group, a substituted or unsubstituted ethylene group, a substituted or unsubstituted propylene group, a substituted or unsubstituted butylene group, a substituted or unsubstituted pentylene group, or a substituted or unsubstituted hexylene group.

For example, the second material may be represented by Chemical Formula 2-1 or Chemical Formula 2-2.

R²-(L²O)ₙ₂—(CH₂)ₘ₃—SiR^{a}R^{b}R^{c} [Chemical Formula 2-1]

In Chemical Formula 2-1,

R² is a substituted or unsubstituted C1 to C20 alkoxy group,

L² is a substituted or unsubstituted C1 to C20 alkylene group,

n2 is an integer of an integer of greater than or equal to 1, and

R^{a}, R^{b}, R^{c}, and m3 are the same as described above.

R²—(CH₂)ₘ₃—SiR^{a}R^{b}R^{c} [Chemical Formula 2-2]

In Chemical Formula 2-2,

R² is hydrogen, an amino group, a substituted or unsubstituted C1 to C20 alkyl group or a substituted or unsubstituted C2 to C20 alkenyl group (e.g., vinyl group, etc.), and

R^{a}, R^{b}, R^{c}, and m3 are the same as described above.

For example, the first and second materials may each independently have a linear type structure. When the first and second materials have a branch-type structure independently including a substituent, slip properties on the substrate surface coated with the surface coating material may be deteriorated. Specifically, since materials having the branch-type structure may hardly realize a brush effect that a material having a long chain lies down on another material having a short chain, slip properties may be deteriorated.

In addition, a self-assembled brush structure of the first and second materials may firmly maintain an inter-chain interaction among adjacent molecular chains and thereby, reduce and/or prevent a bonding damage and/or destruction of the brush structure due to frequent frictions. Accordingly, the surface coating material may be prevented from being easily worn out by the frequent frictions and fortify durability.

The aforementioned surface coating material may be formed into a film by a coating through a solution process or by deposition through a dry process. Accordingly, the film may be a coated film or a deposited film. According to an embodiment, a process of coating the surface coating material on a substrate, for example a glass substrate (glass plate) is provided. Specifically, the coated film may be obtained by coating a solution including the surface coating material dissolved or dispersed in a solvent, for example, in a method of spin coating, slit coating, inkjet printing, spray coating, or dipping and then, drying it. The deposited film may be obtained, for example, in a method of a thermal deposition, a vacuum deposition, or a chemical vapor deposition (CVD).

The film may be formed on a substrate and the substrate may be for example a ceramic or a glass plate, but is not limited thereto.

The film may include a condensation polymerization product of the aforementioned first material and a condensation polymerization product of the aforementioned second material and the first material has a greater weight average molecular weight than the second material.

Herein, the hydrolyzable silane moieties (*—SiR^{a}R^{b}R^{c}) at the terminal end of the first material represented by Chemical Formula 1 and the second material represented by Chemical Formula 2 are bound to the substrate and the moieties at the opposite terminal end are arranged on the surface (air) side. The first and second materials may each independently be arranged along a substantially vertical direction with respect to the substrate.

The condensation polymerization product of the first material and the condensation polymerization product of the second material are the same as described above.

The film may have a contact angle that is not too high by having the moiety represented by the R¹ or R² on the surface. Thus, good slip properties may be obtained. The film may have for example a contact angle of about 60° to about 80°. Herein, the contact angle may be measured by using a Sessile drop technique. A liquid used for measuring the contact angle may be water and a Drop shape analyzer (DSA100, KRUSS, Germany) is used to measure the contact angle by dropping a desired and/or alternatively predetermined amount of water (about 3 ul) on the film.

The film may maintain the contact angle at a desired and/or alternatively predetermined angle after frequent frictions. Durability of the film may be examined through a change of the contact angle after a plurality of frictions. For example, the film may have for example a contact angle change of less than or equal to about 20° after the 5000 times' abrasion test with an eraser under a load of about 1 kg. For example, the film may have a contact angle of about 55° to about 70° after the abrasion test with an eraser under a load of about 1 kg.

On the other hand, the film may be measured with respect to a contact angle by using not water but diiodomethane. Herein, for example, the contact angle may be less than or equal about 52°, for example, less than or equal about 51°, or less than or equal about 50°. Herein, the contact angle may be measured by using a Sessile drop technique. A liquid used for measuring the contact angle may be water and a Drop shape analyzer (DSA100, KRUSS, Germany) is used to measure the contact angle by dropping a desired and/or alternatively predetermined amount of water (about 2.7 ul) on the film.

The substrate and the film may form a stacked structure.

The stacked structure may further include at least one layer between the substrate and the film.

The stacked structure may be a transparent film, for example a transparent flexible film.

For example, the film or the stacked structure may be attached on the display panel. Herein, the display panel and the film or the stacked structure may be directly bonded or may be bonded by interposing an adhesive. The display panel may be for example a liquid crystal panel or an organic light emitting panel, but is not limited thereto. The film or the stacked structure may be disposed on the side of an observer.

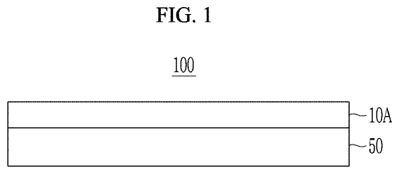

FIG. 1 is a cross-sectional view showing a display device according to an embodiment.

Referring to FIG. 1, a display device 100 according to an embodiment includes a display panel 50 and a functional film 10A.

The display panel 50 may be for example an organic light emitting panel or a liquid crystal panel, for example a bendable display panel, a foldable display panel, or a rollable display panel.

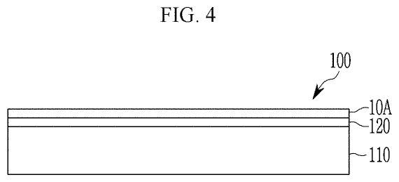

The functional film 10A may include the film or stacked structure and may be disposed on the side of an observer. Another layer may be further disposed between the display panel 50 and the functional film 10A and may include for example a monolayer or plural layers of polymer layer (not shown), a primer layer, and optionally a transparent adhesive layer (not shown). For example, as depicted in FIG. 4, a display device 100 may include another layer 120 (e.g., one or more polymer layers, primer layer, transparent adhesive layer) between the display panel 50 and the functional film 10A.

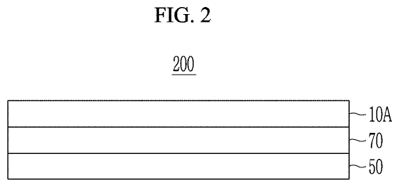

FIG. 2 is a cross-sectional view of a display device according to another embodiment.

Referring to FIG. 2, a display device 200 according to the present embodiment includes a display panel 50, a functional film 10A, and a touch screen panel 70 disposed between the display panel 50 and the functional film 10A.

The display panel 50 may be for example an organic light emitting panel or a liquid crystal panel, for example a bendable display panel, a foldable display panel, or a rollable display panel.

The functional film 10A may include the film or the stacked structure and may be disposed on the side of an observer.

The touch screen panel 70 may be disposed adjacent to each of the functional film 10A and the display panel 50 to recognize the touched position and the position change when is touched by a human hand or an object through the functional film 10A and then to output a touch signal. The driving module (not shown) may monitor a position where is touched from the output touch signal; recognize an icon marked at the touched position, and control to carry out functions corresponding to the recognized icon, and the function performance results are displayed on the display panel 50.

Another layer may be further disposed between the touch screen panel 70 and functional film 10A and may include for example a monolayer or plural layers of polymer layer (not shown) and optionally a transparent adhesive layer (not shown).

Another layer may be further interposed between the touch screen panel 70 and the display panel 50 and may include for example a monolayer or plural layers of polymer layer (not shown) and optionally a transparent adhesive layer (not shown).

The functional film 10A including the aforementioned film or stacked structure may be applied to a variety of electronic devices such as a display device, for example a smart phone, a tablet PC, a camera, a touch screen device, and so on, but is not limited thereto.

Another embodiment provides an article manufactured by coating the aforementioned surface coating material on a substrate, for example, a glass substrate (a glass plate). Herein, the article may include a mobile display device, an automotive display, a sensor, an optical article, and the like but is not limited thereto.

Hereinafter, the embodiments are illustrated in more detail with reference to examples. However, these examples are non-limited examples, and inventive concepts are not limited thereto.

### EXAMPLES

### Example 1

GAM-Long (JSI Silicone Co.) and GAM-Short (JSI Silicone Co.) are used in a mole ratio of 3:1 to prepare a composition. Subsequently, the composition is dry-coated on a glass substrate, thermally deposited with 16 to 20 nm-thick SiO₂, to manufacture a 10 nm-thick or thinner film. The GAM-Long has a structure represented by Chemical Formula GL, and the GAM-Short has a structure represented by Chemical Formula GS.

CH₃O—CH₂CH₂O—(CH₂)₁₀—O—(CH₂)₁₁—Si(OMe)₃ [Chemical Formula GL]

CH₃O—CH₂CH₂O—(CH₂)₁₁—Si(OMe)₃ [Chemical Formula GS]

In Chemical Formulae GL and GS, Me is a methyl group.

### Example 2

A composition is prepared according to the same method as Example 1 except that GAM-Long (JSI Silicone Co.) and GAM-Short (JSI Silicone Co.) are used in a mole ratio of 1:1.

### Example 3

A composition is prepared according to the same method as Example 1 except that GAM-Long (JSI Silicone Co.) and GAM-Short (JSI Silicone Co.) are used in a mole ratio of 1:3.

### Example 4

A composition is prepared according to the same method as Example 1 except that GAM-Long (JSI Silicone Co.) and GAM-Short (JSI Silicone Co.) are used in a mole ratio of 1:7.

### Example 5

A composition is prepared according to the same method as Example 1 except that aminopropyl trimethoxy silane (Sigma-Aldrich Co., Ltd.) is used instead of GAM-Short (JSI Silicone Co.), and the aminopropyl trimethoxy silane and GAM-Long (JSI Silicone Co.) are used in a mole ratio of 1:3. The aminopropyl trimethoxy silane (Sigma-Aldrich Co., Ltd.) is represented by Chemical Formula A.

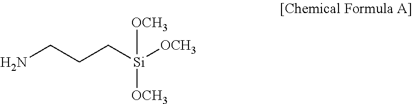 [SMILES: CO[Si](CCCN)(OC)OC]

### Example 6

A composition is prepared according to the same method as Example 5 except that GAM-Long (JSI Silicone Co.) and aminopropyl trimethoxy silane (Sigma-Aldrich Co., Ltd.) are used in a mole ratio of 1:1.

### Example 7

A composition is prepared according to the same method as Example 5 except that GAM-Long (JSI Silicone Co.) and aminopropyl trimethoxy silane (Sigma-Aldrich Co., Ltd.) are used in a mole ratio of 1:3.

### Example 8

A composition is prepared according to the same method as Example 5 except that GAM-Long (JSI Silicone Co.) and aminopropyl trimethoxy silane (Sigma-Aldrich Co., Ltd.) are used in a mole ratio of 1:7.

### Example 9

A composition is prepared according to the same method as Example 1 except that trimethoxy(7-octen-1-yl)-silane (Sigma-Adrich Co., Ltd.) is used instead of GAM-Short (JSI Silicone Co.), and GAM-Long (JSI Silicone Co.) and the trimethoxy(7-octen-1-yl)-silane (Sigma-Adrich Co., Ltd.) are used in a mole ratio of 7:1. The trimethoxy(7-octen-1-yl)-silane (Sigma-Adrich Co., Ltd.) is represented by Chemical Formula B.

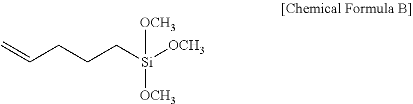

### Example 10

A composition is prepared according to the same method as Example 9 except that GAM-Long (JSI Silicone Co.) and trimethoxy(7-octen-1-yl)-silane (Sigma-Aldrich Co., Ltd.) are used in a mole ratio of 1:1.

### Example 11

A composition is prepared according to the same method as Example 9 except that GAM-Long (JSI Silicone Co.) and trimethoxy(7-octen-1-yl)-silane (Sigma-Aldrich Co., Ltd.) are used in a mole ratio of 1:7.

### Example 12

A composition is prepared according to the same method as Example 1 except that trimethoxy(octyl)silane (Sigma-Aldrich Co., Ltd.) is used instead of GAM-Short (JSI Silicone Co.), and the GAM-Long (JSI Silicone Co.) and trimethoxy(octyl)silane (Sigma-Aldrich Co., Ltd.) are used in a mole ratio of 7:1. The trimethoxy(octyl)silane (Sigma-Aldrich Co., Ltd.) is represented by Chemical Formula C.

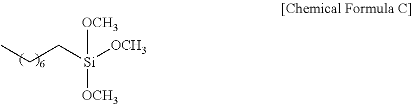

### Example 13

A composition is prepared according to the same method as Example 12 except that GAM-Long (JSI Silicone Co.) and trimethoxy(octyl)silane (Sigma-Aldrich Co., Ltd.) are used in a mole ratio of 1:1.

### Example 14

A composition is prepared according to the same method as Example 12 except that GAM-Long (JSI Silicone Co.) and trimethoxy(octyl)silane (Sigma-Aldrich Co., Ltd.) are used in a mole ratio of 1:7.

### Example 15

A composition is prepared according to the same method as Example 1 except that decyl(trimethoxy)silane (TCI) is used instead of GAM-Short (JSI Silicone Co.), and GAM-Long (JSI Silicone Co.) and the decyl(trimethoxy)silane (TCI) are used in a mole ratio of 7:1. The decyl(trimethoxy)silane (TCI) is represented by Chemical Formula D.

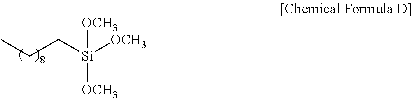

### Example 16

A composition is prepared according to the same method as Example 15 except that GAM-Long (JSI Silicone Co.) and the decyl(trimethoxy)silane (TCI) are used in a mole ratio of 1:1.

### Example 17

A composition is prepared according to the same method as Example 15 except that GAM-Long (JSI Silicone Co.) and the decyl(trimethoxy)silane (TCI) are used in a mole ratio of 1:7.

### Example 18

A composition is prepared according to the same method as Example 1 except that hexadecyl(trimethoxy)silane (Sigma-Aldrich Co., Ltd.) is used instead of GAM-Short (JSI Silicone Co.), and GAM-Long (JSI Silicone Co.) and the hexadecyl(trimethoxy)silane are used in a mole ratio of 7:1. The hexadecyl(trimethoxy)silane (Sigma-Aldrich Co., Ltd.) is represented by Chemical Formula E.

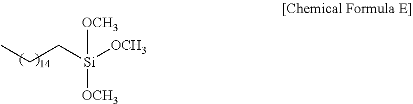

### Example 19

A composition is prepared according to the same method as Example 18 except that GAM-Long (JSI Silicone Co.) and the hexadecyl(trimethoxy)silane (Sigma-Aldrich Co., Ltd.) are used in a mole ratio of 1:1.

### Example 20

A composition is prepared according to the same method as Example 18 except that GAM-Long (JSI Silicone Co.) and the hexadecyl(trimethoxy)silane (Sigma-Aldrich Co., Ltd.) are used in a mole ratio of 1:7.

### Comparative Example 1

A composition is prepared according to the same method as Example 18 except that GAM-Long (JSI Silicone Co.) is used alone.

### Comparative Example 2

A composition is prepared according to the same method as Example 18 except that GAM-Short (JSI Silicone Co.) is used alone.

### Evaluation

### Evaluation I

Slip properties and fingerprint visibility of the films according to Examples 1 to 20 and Comparative Examples 1 and 2 are evaluated.

The slip properties of the films are evaluated by using a friction coefficient, and the fingerprint visibility of the films is evaluated by using an initial contact angle.

The friction coefficient is evaluated by sliding films according to an embodiment with polyurethane and may be easily measured by using a friction coefficient evaluation equipment (Friction/peel tester/FPT-F1, PARAM, Labthink Instrumental, Inc.).

The initial contact angle is evaluated by using a Sessile drop technique method and measured by dropping water and diiodomethane on each film with a Drop shape analyzer (DSA100, KRUSS, Germany).

The friction coefficient and initial contact angle evaluation results are shown in Table 1.

TABLE 1

| | | Initial | Initial |
|---|---|---|---|
| | Friction | contact angle | contact angle |
| | coefficient | (°) | (°) |
| | (w/EtOH) | (water) | (diiodomethane) |
| Example 1 | 0.772 | 70.4 | 40 |
| Example 2 | 0.700 | 71.3 | 40.7 |
| Example 3 | 0.510 | 70.5 | 39.1 |
| Example 4 | 0.921 | 72.3 | 46.8 |
| Example 5 | 0.761 | 69 | 47.2 |
| Example 6 | 0.561 | 69 | 45.5 |
| Example 7 | 1.238 | 71.2 | 48.5 |
| Example 8 | 1.158 | 77 | 47.1 |
| Example 9 | 0.818 | 79 | 50.8 |
| Example 10 | 1.184 | 83.2 | 53.8 |
| Example 11 | 1.101 | 84.6 | 47.6 |
| Example 12 | 0.472 | 71.9 | 43 |
| Example 13 | 1.195 | 67.2 | 42 |
| Example 14 | 0.958 | 71.2 | 41.2 |
| Example 15 | 0.893 | 69.7 | 43.6 |
| Example 16 | 1.096 | 72.5 | 44 |
| Example 17 | 0.073 | 73.7 | 44 |
| Example 18 | 1.179 | 85.4 | 47.3 |
| Example 19 | 0.594 | 81.9 | 49.9 |
| Example 20 | 0.721 | 83.4 | 51.6 |
| Comparative | 1.240 | 76 | 40.1 |
| Example 1 | | | |
| Comparative | 1.28 | 47.7 | 67.8 |
| Example 2 | | | |

Referring to Table 1, the films according to Examples 1 to 20 exhibit a small friction coefficient compared with that of the films according to Comparative Examples 1 and 2 and simultaneously, maintain an initial contact angle within a desired and/or alternatively predetermined range, and accordingly, the films of Examples 1 to 20 exhibit excellent slip properties and fingerprint visibility compared with those of the films of Comparative Examples 1 and 2. Furthermore, Examples 1 to 3, 5, 6, 9, 12, 15, 17, 19, and 20 exhibit much improved slip properties and fingerprint visibility due to a type of a substituent at a terminal end of the second material, a mole ratio of the first and second materials depending thereon, and the like.

While this disclosure has been described in connection with what is presently considered to be practical example embodiments, it is to be understood that inventive concepts are not limited to the disclosed embodiments. On the contrary, inventive concepts are intended to cover various modifications and equivalent arrangements included within the spirit and scope of the appended claims.

### DESCRIPTION OF SYMBOLS

10A: functional layer
50: display panel
70: touch screen panel
100, 200: display device

What is claimed is:

1. A surface coating material, comprising:
a first material represented by Chemical Formula 1, and
a second material represented by Chemical Formula 2,
the first material having a greater weight average molecular weight than the second material,
R¹-(L¹O)ₙ₁—(CH₂)ₘ₁—X—(CH₂)ₘ₂—SiR^{a}R^{b}R^{c} [Chemical Formula 1]
R²-(L²O)ₙ₂—(CH₂)ₘ₃—SiR^{a}R^{b}R^{c} [Chemical Formula 2]
wherein, in Chemical Formula 1 and Chemical Formula 2,
R¹ is hydrogen, a substituted or unsubstituted C1 to C20 alkyl group, or a substituted or unsubstituted C1 to C20 alkoxy group,
R² is hydrogen, an amino group, a substituted or unsubstituted C1 to C20 alkyl group, a substituted or unsubstituted C2 to C20 alkenyl group, or a substituted or unsubstituted C1 to C20 alkoxy group,
L¹ and L² are each independently a substituted or unsubstituted C1 to C20 alkylene group,
X is oxygen, *—OL³-*, or *-L³O—* (L³ is a substituted or unsubstituted C1 to C20 alkylene group),
R^{a}, R^{b}, and R^{c} are each independently hydrogen, a substituted or unsubstituted C1 to C20 alkoxy group, a halogen, a hydroxy group, an amino group, a substituted or unsubstituted C1 to C20 alkyl group, a substituted or unsubstituted C6 to C20 aryl group, or a combination thereof, provided that at least one of R^{a}, R^{b}, and R^{c} is a substituted or unsubstituted C1 to C20 alkoxy group, a halogen, or a hydroxy group,
n1 and n2 each independently are an integer of 0 to 100, and
m1, m2, and m3 each independently are an integer of 1 to 100.

2. The surface coating material of claim 1, wherein
the R² is hydrogen, a substituted or unsubstituted C1 to C20 alkyl group, or a substituted or unsubstituted C1 to C20 alkoxy group, and
m3 is an integer of 3 to 20.

3. The surface coating material of claim 2, wherein
the R² is a substituted or unsubstituted C1 to C20 alkoxy group,
the first material and the second material are included in a mole ratio of about 99:1 to about 25:75.

4. The surface coating material of claim 2, wherein
the R² is hydrogen or a substituted or unsubstituted C1 to C20 alkyl group,
a difference between m1+m2 and m3 is an integer of less than or equal to 6, and
the first material and the second material are included in a mole ratio of about 50:50 to about 1:99.

5. The surface coating material of claim 2, wherein
the R² is hydrogen or a substituted or unsubstituted C1 to C20 alkyl group,
a difference between m1+m2 and m3 is an integer of 7 to 13, and
the first material and the second material are included in a mole ratio of about 99:1 to about 87.5:12.5 or about 12.5:87.5 to about 1:99.

6. The surface coating material of claim 2, wherein
the R² is hydrogen or a substituted or unsubstituted C1 to C20 alkyl group,
a difference between m1+m2 and m3 is an integer of greater than or equal to 14, and
the first material and the second material are included in a mole ratio of about 99:1 to about 87.5:12.5.

7. The surface coating material of claim 1, wherein
the R² is an amino group, and
m3 is an integer of 1 to 4.

8. The surface coating material of claim 7, wherein the first material and the second material are included in a mole ratio of about 99:1 to about 50:50.

9. The surface coating material of claim 1, wherein
the R² is a substituted or unsubstituted C2 to C20 alkenyl group, and
m3 is an integer of 5 to 7.

10. The surface coating material of claim 9, wherein the first material and the second material are included in a mole ratio of about 99:1 to about 87.5:12.5.

11. The surface coating material of claim 1, wherein
the first material has a weight average molecular weight of about 350 g/mol to about 1,500 g/mol, and
the second material has a weight average molecular weight of about 150 g/mol to about 1,000 g/mol.

12. The surface coating material of claim 1, wherein the first material has a longer chain length than the second material.

13. The surface coating material of claim 1, wherein
n3 is 1.

14. An article comprising:
a glass substrate coated with the surface coating material of claim 1.

15. A film comprising
a condensation polymerization product of a first material represented by Chemical Formula 1, and
a condensation polymerization product of a second material represented by Chemical Formula 2
the first material having a greater weight average molecular weight than the second material,
R¹-(L¹O)ₙ₁—(CH₂)ₘ₁—X—(CH₂)ₘ₂—SiR^{a}R^{b}R^{c} [Chemical Formula 1]
R²-(L²O)ₙ₂—(CH₂)ₘ₃—SiR^{a}R^{b}R^{c} [Chemical Formula 2]
wherein, in Chemical Formula 1 and Chemical Formula 2,
R¹ is hydrogen, a substituted or unsubstituted C1 to C20 alkyl group, or a substituted or unsubstituted C1 to C20 alkoxy group,
R² is hydrogen, an amino group, a substituted or unsubstituted C1 to C20 alkyl group, a substituted or unsubstituted C2 to C20 alkenyl group, or a substituted or unsubstituted C1 to C20 alkoxy group,
L¹ and L² are each independently a substituted or unsubstituted C1 to C20 alkylene group,
X is oxygen, *—OL³-*, or *-L³O—* (L³ is a substituted or unsubstituted C1 to C20 alkylene group),
R^{a}, R^{b}, and R^{c} are each independently hydrogen, a substituted or unsubstituted C1 to C20 alkoxy group, a halogen, a hydroxy group, an amino group, a substituted or unsubstituted C1 to C20 alkyl group, a substituted or unsubstituted C6 to C20 aryl group, or a combination thereof, provided that at least one of R^{a}, R^{b}, and R^{c} is a substituted or unsubstituted C1 to C20 alkoxy group, a halogen, or a hydroxy group,
n1 and n2 each independently are an integer of 0 to 100, and
m1, m2, and m3 each independently are an integer of 1 to 100.

16. The film of claim 15, wherein
the R² is hydrogen, a substituted or unsubstituted C1 to C20 alkyl group, or a substituted or unsubstituted C1 to C20 alkoxy group, and
m3 is an integer of 3 to 20.

17. The film of claim 16, wherein
the R² is a substituted or unsubstituted C1 to C20 alkoxy group,
the first material and the second material are included in a mole ratio of about 99:1 to about 25:75.

18. The film of claim 16, wherein
the R² is hydrogen or a substituted or unsubstituted C1 to C20 alkyl group,
a difference between m1+m2 and m3 is an integer of less than or equal to 6, and
the first material and the second material are included in a mole ratio of about 50:50 to about 1:99.

19. The film of claim 16, wherein
the R² is hydrogen or a substituted or unsubstituted C1 to C20 alkyl group,
a difference between m1+m2 and m3 is an integer of 7 to 13, and
the first material and the second material are included in a mole ratio of about 99:1 to about 87.5:12.5 or about 12.5:87.5 to about 1:99.

20. The film of claim 16, wherein
the R² is hydrogen or a substituted or unsubstituted C1 to C20 alkyl group,
a difference between m1+m2 and m3 is an integer of greater than or equal to 14, and
the first material and the second material are included in a mole ratio of about 99:1 to about 87.5:12.5.

21. The film of claim 15, wherein
the R² is an amino group, and
m3 is an integer of 1 to 4.

22. The film of claim 21, wherein the first material and the second material are included in a mole ratio of about 99:1 to about 50:50.

23. The film of claim 15, wherein
the R² is a substituted or unsubstituted C2 to C20 alkenyl group, and
m3 is an integer of 5 to 7.

24. The film of claim 23, wherein the first material and the second material are included in a mole ratio of about 99:1 to about 87.5:12.5.

25. The film of claim 15, wherein
the first material has a weight average molecular weight of about 350 g/mol to about 1,500 g/mol, and
the second material has a weight average molecular weight of about 150 g/mol to about 1,000 g/mol.

26. The film of claim 15, wherein the first material has a longer chain length than the second material.

27. The film of claim 15, wherein
n3 is 1.

28. A stacked structure comprising
a substrate, and
the film of claim 15.

29. The stacked structure of claim 28, wherein the substrate is a ceramic or a glass plate.

30. A display device comprising the film of claim 15.

31. A display device comprising the stacked structure of claim 28.
